(19) United States
(12) Patent Application Publication
(10) Pub. No.: US 2012/0309163 A1
(43) Pub. Date: Dec. 6, 2012

(54) METHOD OF FORMING TITANIUM OXIDE FILM HAVING RUTILE CRYSTALLINE STRUCTURE

(75) Inventors: Takakazu KIYOMURA, Chuo-ku (JP); Toshiyuki HIROTA, Chuo-ku (JP); Yuichiro MOROZUMI, Nirasaki City (JP); Shingo HISHIYA, Nirasaki City (JP)

(73) Assignees: TOKYO ELECTRON LIMITED, Tokyo (JP); ELPIDA MEMORY, INC., Tokyo (JP)

(21) Appl. No.: 13/476,617

(22) Filed: May 21, 2012

(30) Foreign Application Priority Data
May 31, 2011 (JP) 2011-121877

(51) Int. Cl. H01G 13/00; H01L 21/02

(52) U.S. Cl. 438/396; 427/79; 257/E21.011

(57) ABSTRACT

The invention provides a method of forming a titanium oxide film having a rutile crystalline structure that has high permittivity. The titanium oxide film having a rutile crystalline structure is produced by forming an amorphous titanium oxide film on an amorphous zirconium oxide film using methyl cyclopentadienyl tris(dimethylamino)titanium as a titanium precursor by an ALD method, and crystallizing the amorphous titanium oxide film by annealing at a temperature of 300° C. or higher.

### BACKGROUND OF THE INVENTION

1. Field of the Invention

The present invention relates to a method of forming a titanium oxide (TiO₂) film having a rutile crystalline structure, and more particularly, to a method of forming a film, which can be formed at a temperature of 700° C. or less, and also has excellent leakage current characteristics as a high-permittivity insulating film that is used in a capacitor.

2. Related Art

As the miniaturization of semiconductor devices such as dynamic random access memory (DRAM), a high-permittivity insulating film that is used in a capacitor is required.

Titanium oxide (TiO₂) can be regarded as an insulating material having high permittivity. In TiO₂, two phases, i.e., an anatase phase and a rutile phase, are present as well-known crystalline structures. The anatase phase is a low-temperature phase that can be easily formed at a relatively low temperature, and the crystal of the anatase phase has a low relative permittivity that is slightly smaller than 40. In contrast, the rutile phase is a high-temperature phase, and the crystal of the rutile phase has a high relative permittivity that is 80 or more. When the crystal of the rutile phase is used as an insulating material that is used in a capacitor, it is possible to manufacture a high-capacitance capacitor.

The TiO₂ film can be formed by a variety of methods, such as sputtering, chemical vapor deposition (CVD), or atomic layer deposition (ALD).

When used in semiconductor devices, the ALD method is mainly used at present in terms of miniaturization.

For example, according to experiments by Gyeong Teak Lim et al. (Thin Solid Films 498 (2006) p 254-258), a TiO₂ film is formed on silicon using a precursor, tetrakis(dimethylamino)titanium (TDMAT) and an oxidizer, H₂O, by an ALD method. The TiO₂ film is amorphous right after being formed, and is crystallized when annealed. The anatase phase is formed by annealing at a temperature of 300° C. or higher, a mixture of the rutile phase and the anatase phase is formed for the first time at a temperature of 700° C. or higher, and the rutile phase becomes the main structure in the crystalline structure at a temperature of 800° C. or higher. However, in the semiconductor process, it is difficult to perform annealing at a high temperature in order to protect semiconductor devices, such as a transistor, from adverse effects due to the progress of the miniaturization. In consideration of application to capacitors, the annealing performed at a high temperature causes the surface of the electrode to be oxidized, thereby causing problems such as increased resistance and decreased adherence, when a metal film, particularly, a titanium nitride (TiN) film for general use is used as a lower electrode. Therefore, in spite of the intention to produce the rutile phase crystal, the annealing at such a high temperature cannot be performed

In addition, JP2000-254519A discloses a technology for lowering the temperature of transition from an anatase phase to a rutile phase by radiating Ar ion beams in order to form a stacking structure of a rutile TiO₂ film and an anatase TiO₂ film in use for an optical catalyst. However, even this means requires annealing at a temperature of 500° C. or higher in order to produce a TiO₂ film having a rutile crystalline structure. In addition, if forming the TiO₂ film in a place that has a three-dimensional structure, such as a capacitor of a DRAM device; it would be difficult to uniformly introduce Ar ions via ion radiation.

In addition, JP2007-110111A discloses a technology for producing a rutile TiO₂ film at a low temperature of 400° C. or below by forming a RuO₂ film on the surface of a lower electrode made of ruthenium (Ru), which is in use for a capacitor. However, since the material of the lower electrode is limited to Ru, it is difficult to produce a capacitor having better performance by changing the material of the electrode.

### SUMMARY

Therefore, the inventors have closely investigated a method of forming a TiO₂ film, by which the TiO₂ film having a rutile crystalline structure can be formed at a temperature as low as possible, and the uniform TiO₂ film can be easily formed without being affected by a shape or material of a base electrode.

According to the results of experiments performed to form a TiO₂ film by an ALD method, methods of forming a TiO₂ film directly on a titanium nitride (TiN) film, which is typically used for a lower electrode, tend to form anatase phase crystals. In addition, even after every possible attempt was made to an annealing method, it was difficult to produce a TiO₂ film that has only rutile phase crystals.

At first, the inventors were investigating an insulation film for a capacitor that has a multilayer structure of zirconium oxide (ZrO₂) and titanium oxide (TiO₂) (also referred to as a TZ structure). In the process of investigating this structure, the inventors found that a TiO₂ film having a rutile crystalline structure can be formed without requiring high-temperature annealing when the TiO₂ film is formed on a ZrO₂ film under specific conditions.

Specifically, according to an embodiment of the invention, provided is a method of forming a titanium oxide film having a rutile crystalline structure. The method includes the processes of: forming an amorphous zirconium oxide film, forming an amorphous titanium oxide film on the amorphous zirconium oxide film using methyl cyclopentadienyl tris(dimethylamino)titanium as a titanium precursor by an atomic layer deposition (ALD) method, and crystallizing at least the amorphous titanium oxide film by annealing at a temperature of 300° C. or higher.

In addition, according to another embodiment of the invention, provided is a method of manufacturing a semiconductor device, which includes a capacitor. The method includes the processes of: forming an amorphous zirconium oxide film on a lower electrode for the capacitor, forming an amorphous titanium oxide film on the zirconium oxide film using methyl cyclopentadienyl tris(dimethylamino)titanium as a titanium precursor by an ALD method, crystallizing at least the amorphous titanium oxide film by annealing at a temperature ranging from 300° C. to 700° C., and forming an upper electrode for the capacitor on the annealed titanium oxide film.

According to an embodiment of the invention, it is possible to easily produce a titanium oxide film having a rutile crystalline structure at a low temperature, which was difficult to form in the related art.

In addition, it is possible to provide a semiconductor device having a capacitor that also has excellent leakage current characteristics by optimizing the thickness of the zirconium oxide film in the base.

### BRIEF DESCRIPTION OF THE DRAWINGS

The above features and advantages of the present invention will be more apparent from the following description of certain preferred embodiments taken in conjunction with the accompanying drawings, in which:

FIG. 1 is an X-ray diffraction diagram when a TiO film is formed on a crystalline ZrO film according to Experimental Example 1;

FIG. 2A and FIG. 2B are X-ray diffraction diagrams when a TiO film is formed on an amorphous ZrO film according to Experimental Example 2;

FIG. 3 is a graph depicting variation in the permittivity of a TiO film depending on the film thickness of a ZrO film according to Experimental Example 3;

FIG. 4 is a graph depicting relationship between variation in the permittivity of a TiO film depending on the thickness of a ZrO film according to Experimental Example 3 and leakage current ratios;

FIG. 5A to FIG. 5C are schematic views illustrating capacitor structures in which an Al-doped layer is provided;

FIG. 6 is a schematic cross-sectional view of a semiconductor device depicting an application of the invention;

FIG. 7 is a plan view of the position marked by X-X in FIG. 6; and

FIG. 8A to FIG. 8I are cross-sectional views depicting processes of manufacturing the capacitor shown in FIG. 6.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

The inventors were investigating to form the foregoing TZ structure, first, using zirconium oxide (hereinafter, referred to as ZrO) as a main structure and forming a film of titanium oxide (hereinafter, referred to as TiO) as a protective film. In this step, the TiO film does not have a rutile crystalline structure, but has an amorphous structure or an anatase crystalline structure even though the TiO film is crystallized. Once a crystal of the anatase crystalline structure is formed, conversion into the rutile crystalline structure requires a very high temperature of 800° C. or higher.

### Experimental Example 1

First, in consideration of application to a capacitor, a TiN film having a thickness of 10 nm was formed as a lower electrode on a substrate, and then a ZrO film was formed thereon. The formation of the ZrO film was performed by repeating process steps a desired number of times, the process steps including (1) introducing a Zr source into a reaction chamber and causing the Zr source to be adsorbed on the surface of the TiN film, (2) discharging the remaining amount of the Zr source that was not adsorbed by a purge gas, such as N₂ or Ar, from the reaction chamber, (3) oxidizing the Zr source using a reaction gas such as O₃, and (4) purging the remaining amount of the reaction gas that has not reacted. Here, the ZrO film was formed at a thickness of 6 nm. The formed ZrO film was a crystalline film.

In sequence, a TiO film was formed on the resultant ZrO film by an ALD method. The formation of the TiO film was performed by repeating process steps a desired number of times, the process steps including (1) introducing a Ti source into the reaction chamber and causing the Ti source to be adsorbed on the surface of the ZrO film, (2) discharging the remaining amount of the Ti source that was not adsorbed by a purge gas, such as N₂ or Ar, from the reaction chamber, (3) oxidizing the Ti source using a reaction gas such as O₃, and (4) purging the remaining amount of the reaction gas that has not reacted. Here, the thickness of the formed TiO film was 8 nm.

As the Ti source (a Ti precursor), the following two compounds were used, respectively. In the ALD method, the temperature at which the films were formed was 250° C. for both the ZrO film and the TiO film.

| Abbreviation | | MCPDTMT |
|---|---|---|
| Chemical | TIPT | Methyl cyclopentadienyl tris |
| Name | Tetraisopropoxy titanium | (dimethylamino) titanium |
| Structural Formula | 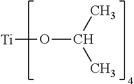 | 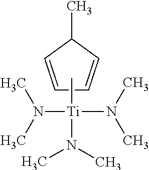 |

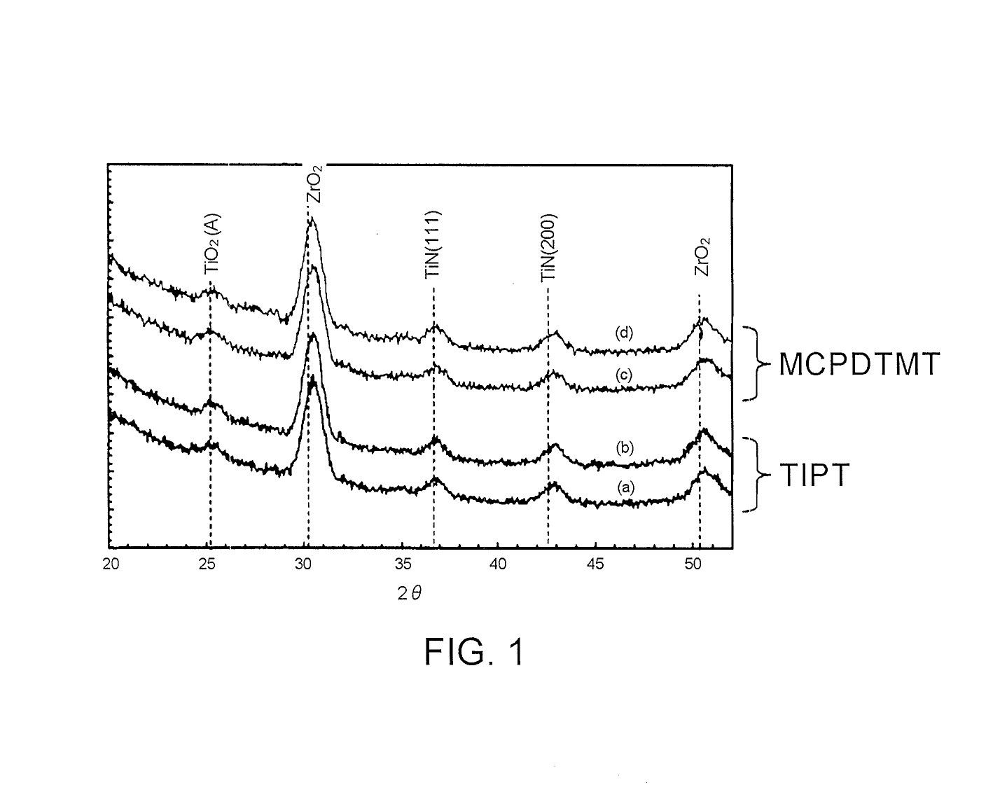

As for the TiO film that was formed, X-ray diffraction diagrams of films as depo and the films after annealing at a temperature of 600° C. are presented in FIG. 1. In FIG. 1, (a) indicates the diffraction of the film as depo when TIPT was used as a Ti precursor, (b) indicates the diffraction of the film after annealing at a temperature of 600° C. when TIPT was used as a Ti precursor, (c) indicates the diffraction of the film as depo when MCPDTMT was used, and (d) indicates the diffraction of the film after annealing at a temperature of 600° C. when MCPDTMT was used. As can be seen from the diagrams, the peak of a rutile crystalline structure, which would otherwise appear in the vicinity of 27°, was not observed irrespective of the types of the Ti precursors that were used, but only the peak of an anatase crystalline structure was observed in the vicinity of 25°. In addition, due to the peak being observed in the films as depo (a and c), it can be regarded that the TiO film as depo has the anatase crystalline structure.

### Experimental Example 2

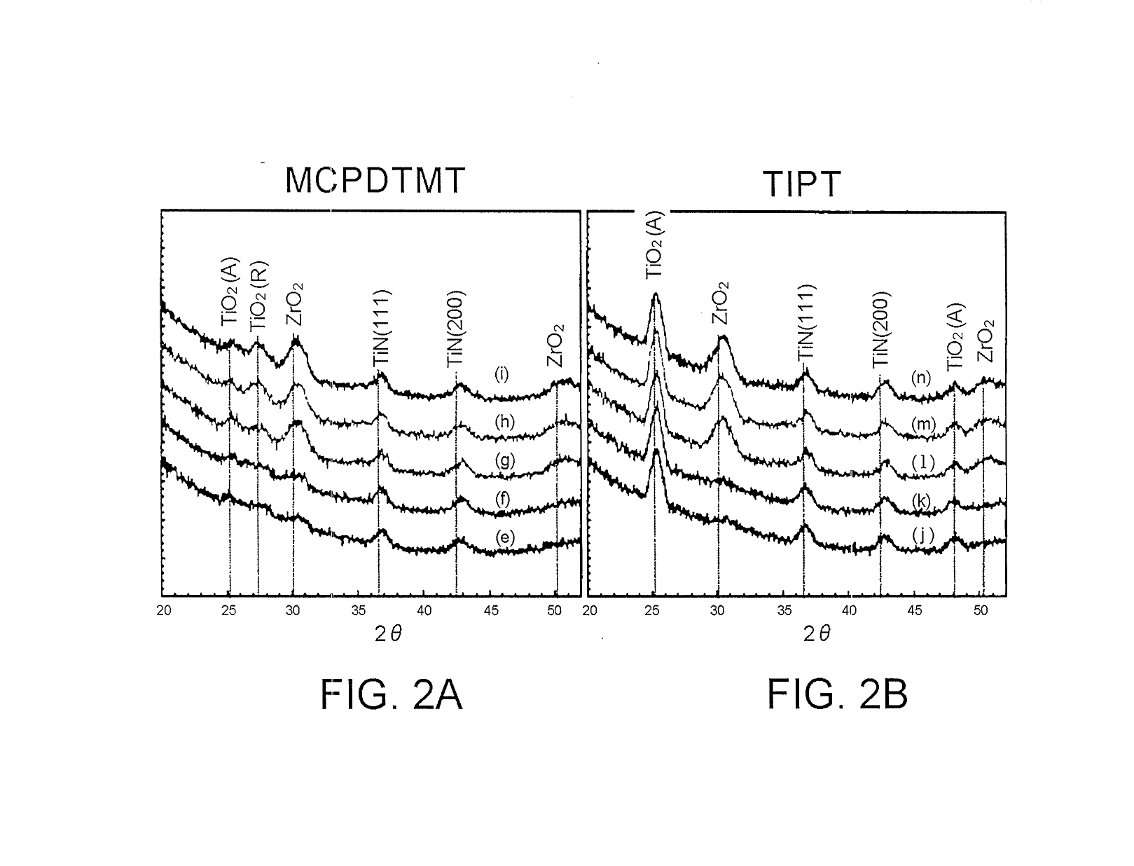

The formation of a TiO film on a ZrO film was performed in the same way as in Experimental Example 1 by changing the thickness of the ZrO film to 4 nm. Likewise, the results of performing X-ray diffraction were presented in FIG. 2. Here, annealing was performed under 4 temperature conditions, including 280° C., 300° C., 400° C. and 600° C. The annealing was performed in an oxidizing atmosphere at respective temperatures for 10 minutes. In FIG. 2A and FIG. 2B, FIG. 2A in the left presents the results when MCPDTMT was used as a Ti precursor, (e) as depo, (f) annealing at 280° C., (g) annealing at 300° C., (h) annealing at 400° C., and (i) annealing at 600° C., and FIG. 2B in the right presents the results when TIPT was used as a Ti precursor, (j) as depo, (k) annealing at 280° C., (l) annealing at 300° C., (m) annealing at 400° C., and (n) annealing at 600° C.

In the result (e) as depo using the MCPDTMT, only the peak of TiN of the lower electrode was observed, but no peak was identified from ZrO₂ or TiO₂. Therefore, it can be appreciated that the ZrO film is amorphous and the TiO film as depo is also amorphous. Afterwards, the peak (TiO₂ (R)) of the rutile crystalline structure was observed due to the annealing at the temperatures of 300° C. or higher. In addition, the ZrO₂ peak appeared since the ZrO film was subjected to crystallization. In the result (j) as depo using TIPT, the ZrO₂ peak was not observed in the same way, but a peak (TiO₂ (A)) based on the anatase crystalline structure was observed. It can be appreciated that the film that has the anatase crystalline structure once is not transformed into the rutile crystalline structure due to annealing up to 600° C.

Accordingly, it can be appreciated that the TiO film having the rutile crystalline structure can be formed by forming a TiO film on a base ZrO film of an amorphous state by using MCPDTMT as a Ti precursor, and followed by annealing the TiO film at a temperature of 300° C. or higher.

### Experimental Example 3

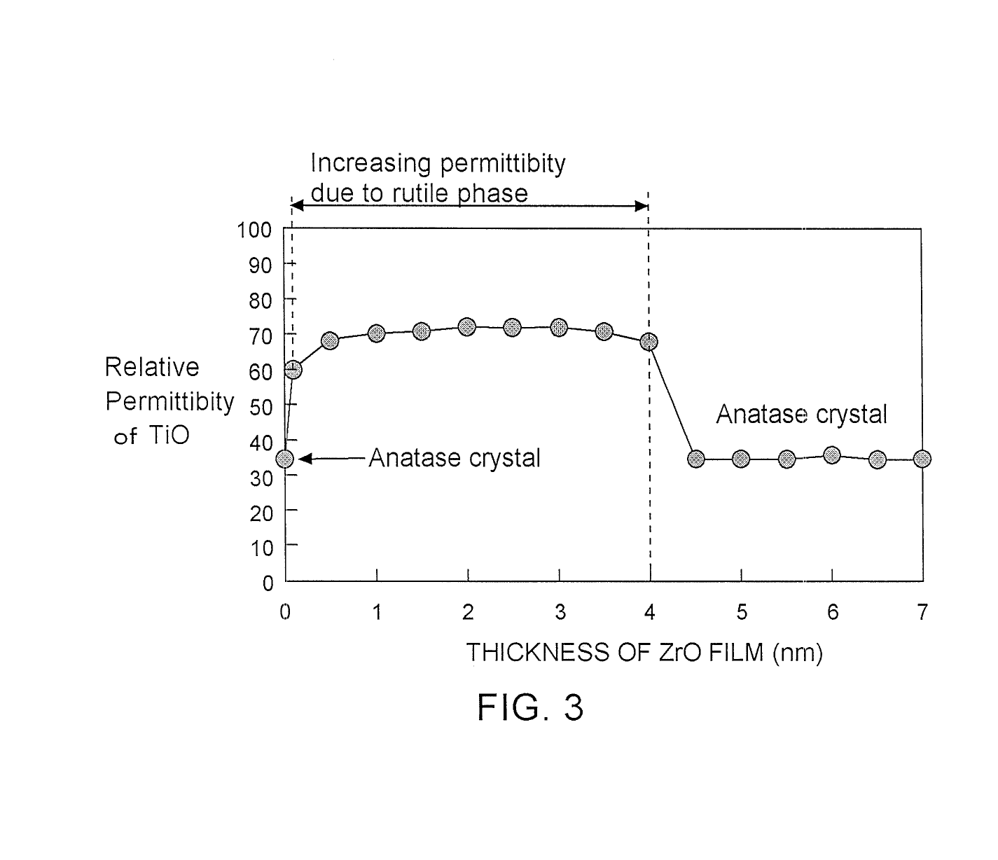

Next, it was verified whether or not a TiO film formed using MCPDTMT, in which the formation of the rutile crystalline structure was identified, can be used as a dielectric film for a capacitor by changing the thickness of a base ZrO film. In the experiment, the thickness of the TiO film was fixed to 8 nm, and the thickness of the ZrO film was varied up to 7 nm. The results obtained by measuring the relative permittivity of TiO films that were formed after being annealed at 600° C. are presented in FIG. 3. At thicknesses of the ZrO film ranging from 0.1 nm to 4 nm, high-permittivity TiO films were produced since the rutile phase was obtained. When the thickness of the ZrO film exceeds 4 nm, the anatase crystalline structure appeared, thereby lowering the relative permittivity. When the TiO film is directly formed on the TiN film (the thickness of the ZrO film is 0 nm), the anatase crystalline structure also appeared, thereby lowering the relative permittivity.

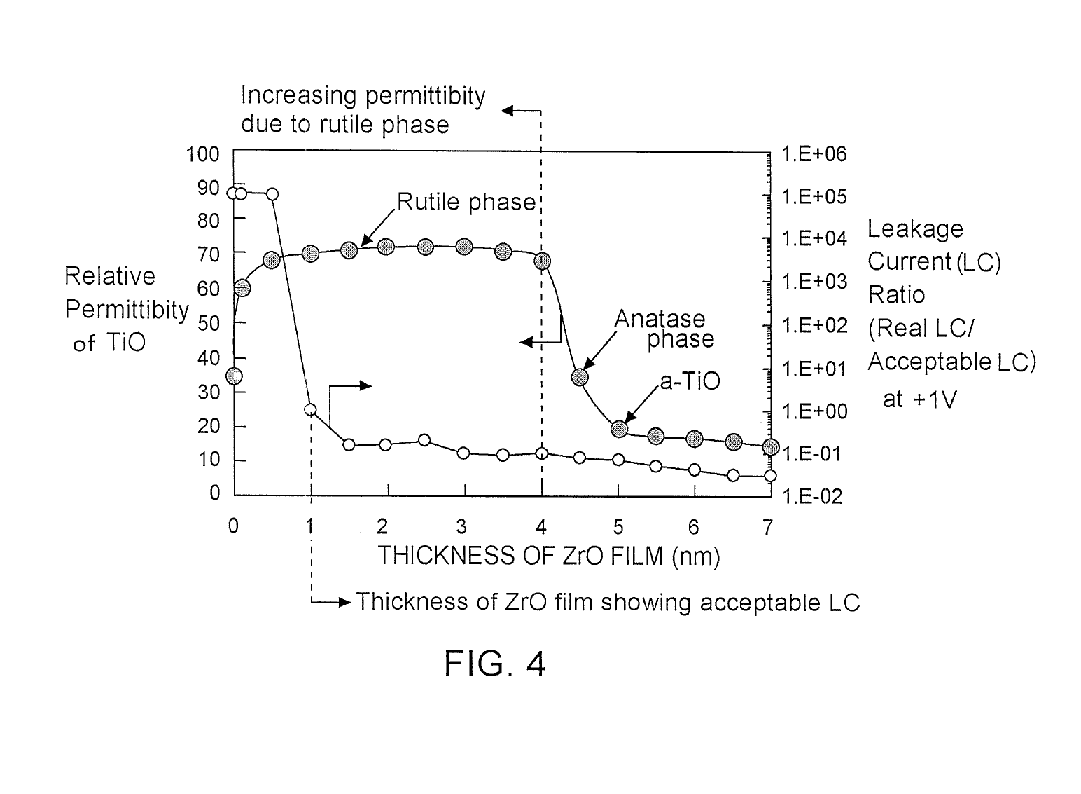

In sequence, when the sum of the thickness of the ZrO film and the thickness of the TiO film was set 8 nm, and the relative permittivity and the leakage current ratio (actual leak/acceptable leak) of the TiO film (after being annealed at 600° C.) at +1.0 V were measured. The measurement of the leakage current ratio was performed by forming a RuO₂ film as an upper electrode, and applying a voltage between the upper and lower electrodes. The results are presented in FIG. 4. Like FIG. 3, the relative permittivity of the TiO film is high at thicknesses of the ZrO film ranging from 0.1 nm to 4 nm. However, in the range in which the thickness is less than 1 nm, the leakage current ratio shows an increase. In the range in which the thickness is greater than 4 nm but does not exceed 4.5 nm, the TiO film has an anatase phase, thereby showing a decrease in the permittivity. When the thickness of the ZrO film exceeds 4.5 nm, due to the decreased thickness of the TiO film, the TiO film remains in the amorphous state even though annealing is performed at a temperature of 300° C. or higher, and the relative permittivity is about 20. Accordingly, it is preferred that the thickness of the ZrO film be 1 nm or more in order to satisfy the acceptable leak value. Therefore, it was appreciated that the film that has excellent relative permittivity and excellent leakage current characteristics can be produced at thicknesses of the ZrO film ranging from 1 nm to 4 nm. In addition, crystallization is possible since the thickness of the TiO film is 3.5 nm or more. Particularly, it is preferred that the thickness of the TiO film be 4 nm or more.

In practice, in the case of being applied to a capacitor, it is possible to use TiN for the lower electrode. Here, it is also possible to use a material having a higher work function, in particular, a material having a high work function of 5.1 eV or higher, such as Pt, Ru or RuO₂. In the present invention, the ability to use TiN for the lower electrode is especially advantageous for application to a capacitor having a three-dimensional structure. It is preferred that a material having a high work function be used for the upper electrode, which directly abuts the TiO film. When the TiN film is formed as the upper electrode, the capacitor characteristic may degrade due to a Schottky contact with the TiO film.

A precursor that is known in the related art may be used as the Zr source, which is used in forming the ZrO film. The examples of the Zr source may include tetrakis(ethymethylamino)zirconium (abbreviation: ‘TEMAZ’), cyclopentadienyl tris(dimethylamino)zirconium (ZrCp(NMe₂)₃; abbreviation: ‘CPTMAZ’), methylcyclopentadienyl tris(dimethylamino)zirconium (Zr(MeCp)(NMe₂)₃; abbreviation: ‘MCPTMAZ’), and the like. Here, the CPTMAZ has a structure similar to a Ti precursor, MCPDTMT, which is used in the present invention.

The ZrO film having a thickness ranging from 1 nm to 4 nm is formed in the amorphous state, and afterwards, may be crystallized when annealing for the crystallization of the TiO film is performed. At a thickness of the film of 2 nm or less, the ZrO film often remains in the amorphous state even after being annealed.

In the deposition of the TiO film, the ZrO film is required to remain the amorphous state. When the TiO film is deposited at a temperature where the ZrO film is crystallized, a TiO film having an anatase structure is created, as presented in Experimental Example 1. Therefore, although the temperature in the deposition of the TiO film may vary depending on the thickness of the ZrO film that is formed, it is preferably below the crystallization temperature of the ZrO film. It is preferred that the temperature be below 300° C., and particularly, below 250° C.

The annealing for crystallizing the TiO film, which is formed in the amorphous state, is performed at a temperature of 300° C. or higher, as described above. When being applied as a dielectric film of a capacitor, particularly, as a capacitor dielectric film for a semiconductor device, the temperature is preferably 700° C. or lower, and more preferably 600° C. or lower. The annealing may be performed in any one of an oxidizing gas atmosphere and an inert gas atmosphere. It is preferred that the annealing be performed in an oxidizing gas atmosphere.

In the case of being used as a dielectric film of a capacitor, the leakage current characteristics can be improved by doping the inside of the ZrO film or the TiO film with aluminum (Al). However, it is preferred that the aluminum be added at a faint or very small amount, since the relative permittivity decreases due to increasing the Al doping. In the case of being doped Al into the TiO film, it is preferred that the Al doping be performed after an undoped TiO film is deposited to a predetermined amount on the ZrO film. This is because the Al doping facilitates the creation of the anatase phase.

For a method of doping with a faint amount of Al, an adsorption site blocking-atomic layer deposition (ASB-ALD) method proposed by the inventors is advantageous. The ASB-ALD method includes blocking Al precursor adsorption sites in advance using a Zr precursor or a Ti precursor that has a functional group without affinity for an Al precursor, and then introducing the Al precursor into a film-forming space, whereby the adsorption sites are limited to the state in which they maintain in-plane uniformity, and the adsorption does not occur on the functional group at the surface of the Zr precursor or the Ti precursor that is adsorbed on a base, so that the doping with a faint amount of Al is possible.

When the Al doped layer is clearly formed, it is known that permittivity decreases due to the so-called ‘size effect’ since the Al doped layer divides upper and lower crystalline layers. However, the ASB-ALD method can suppress the size effect by doping a faint amount of Al such that the plane density of Al atoms in one layer is less than 1.4 E+14 atoms/cm².

CPTMAZ, MCPTMAZ, and MCPDTMT, which are used in the present invention, are suitably used as the Zr precursor or the Ti precursor in the ASB-ALD method.

Describing the ASB-ALD process in brief, the ASB-ALD process is performed by repeating process steps a desired number of times, the process steps including (1) causing the Zr precursor or the Ti precursor to be adsorbed on the surface of the base, (2) discharging the remaining amount of the Zr precursor or the Ti precursor that is not adsorbed by a purge gas, such as N₂ or Ar, (3) introducing the Al precursor and causing the Al precursor to be adsorbed on limited sites, on which the Zr precursor or the Ti precursor is not adsorbed in the former step, (4) discharging the remaining amount of the Al precursor that is not adsorbed by a purge gas, such as N₂ or Ar, (5) oxidizing the respective precursors using a reaction gas, such as O₃, and (6) purging the remaining amount of the reaction gas that has not reacted.

When the thickness of the ZrO film is limited to a range from 1 nm to 4 nm, the ZrO film is already influenced by the size effect. When the thickness is 2 nm or less, the ZrO film becomes an amorphous film, the relative permittivity of which is inferior to that of a crystalline film. Therefore, the Al doping may be performed using a method other than the ASB-ALD method, for example, by using TEMAZ as a Zr precursor.

The conceptual diagrams of capacitors, which are produced in this way, are illustrated in FIG. 5A to FIG. 5C. FIG. 5A shows a structure that includes an underlying lower electrode 1, an undoped ZrO film 2, an Al-doped TiO film 3, and an upper electrode 4. FIG. 5B shows a structure that includes an underlying lower electrode 1, an Al-doped ZrO film 5, an undoped TiO film 6, and an upper electrode 4. FIG. 5C shows a structure that includes an underlying lower electrode 1, an Al-doped ZrO film 5, an Al-doped TiO film 3, and an upper electrode 4. The capacitor structure according to the invention is not limited to these examples, but other layer(s) may be added as long as the effect of the invention is not impaired. In an example, an amorphous TiO film having a thickness of 1 nm or less may be provided as a protective film between the lower electrode and the ZrO film. Although the thin TiO film is not crystallized by annealing and has low permittivity as described above, it has an effect of preventing the leakage current from increasing due to the crystallization of the ZrO film.

### Application to Capacitor Having Three-Dimensional Structure

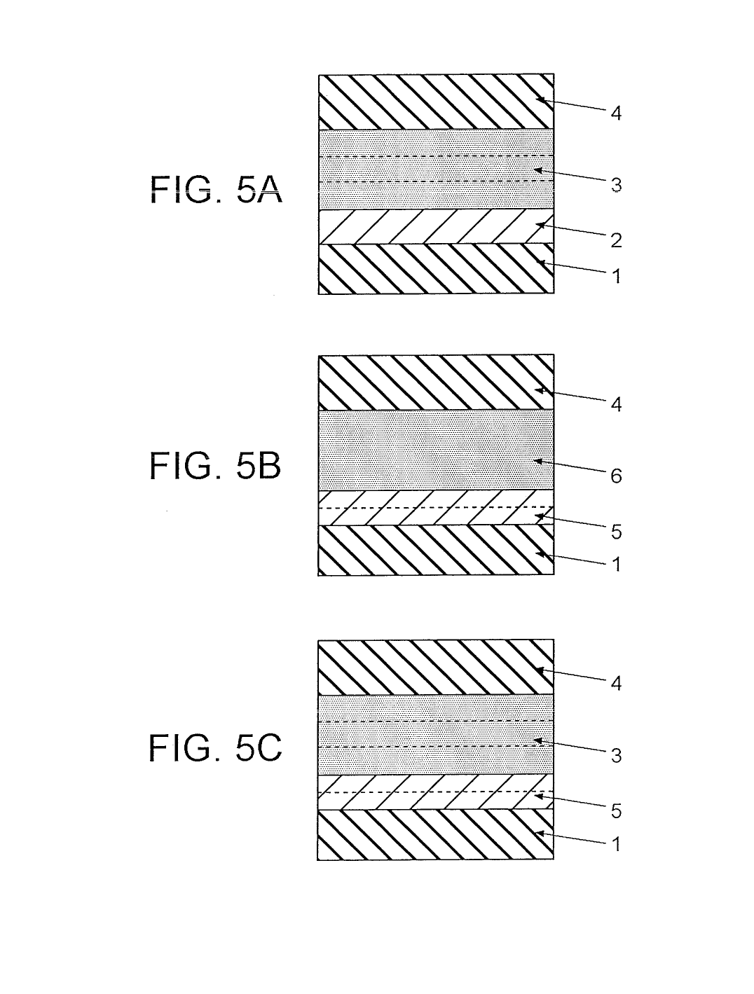

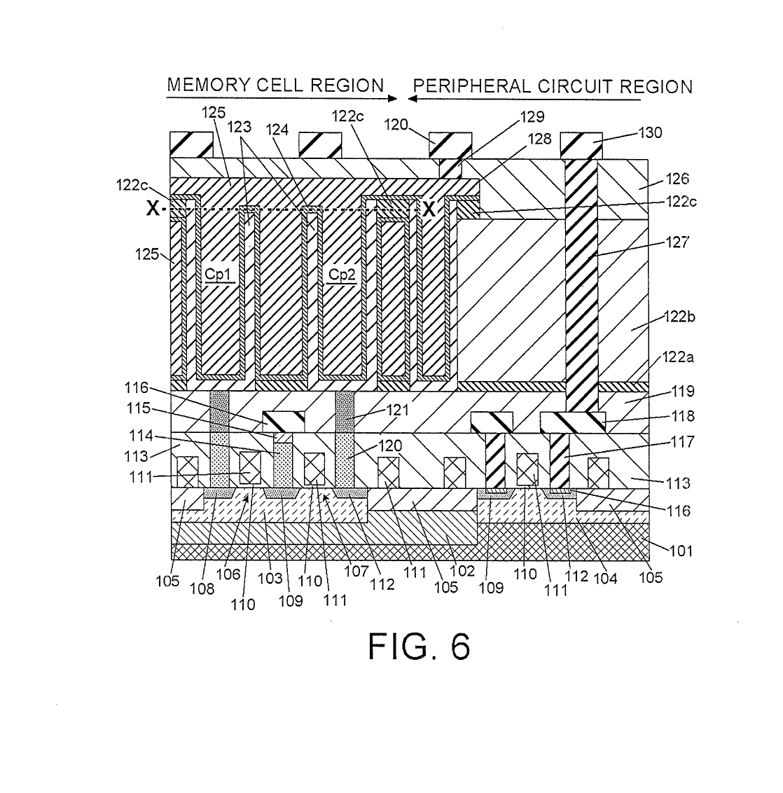

In this example, a semiconductor device which is applied to a capacitor having a three-dimensional structure of an aspect ratio of 20 or more using the method of the invention will be described with reference to FIG. 6 and FIG. 7.

First, the overall construction of DRAM, which is to form a semiconductor memory device, will be described with reference to the schematic cross-sectional view of FIG. 6.

An n-well 102 is formed in a p-type silicon substrate 101, and a first p-well 103 is formed inside the n-well 102. A second p-well 104 is formed in a region except for the n-well 102, and is separated from the first p-well 103 by a separation region 105. For the sake of convenience, the first p-well 103 indicates a memory cell region on which a plurality of memory cells are disposed, and the second p-well 104 indicates a peripheral circuit region.

In the first p-well 103, switching transistors 106 and 107 are formed as respective components of the memory cells, and have a gate electrode that forms a word line. The transistor 106 includes a drain 108, a source 109 and a gate electrode 111, with a gate insulation film 110 being interposed therebetween. The gate electrode 111 has a polycide structure, in which tungsten silicide is layered on polycrystalline silicon, or a polymetal structure, in which tungsten is layered on polycrystalline silicon. The transistor 107 shares the source 109, and includes a drain 112 and a gate electrode 111, with a gate insulation film 110 being interposed therebetween. The transistors are covered with a first interlayer insulation film 113.

A contact-hole, which is provided in a predetermined region of the first interlayer insulation film 113 so as to reach the source 109, is filled with polycrystalline silicon 114. Metal silicide 115 is provided on the surface of the polycrystalline silicon 114. A bit line 116 which is made of tungsten nitride and tungsten is provided so as to contact the metal silicide 115. The bit line 116 is covered with a second interlayer insulation film 119.

A contact-hole is provided in a predetermined region of the first interlayer insulation film 113, and a contact-hole is provided in a predetermined region of the second interlayer insulation film 119. The contact-holes are filled with silicon so as to contact the transistor drain 108 and to contact the transistor drain 112, thereby forming silicon plugs 120. Conductive plugs 121 made of metal are provided on the respective silicon plugs 120.

A capacitor is formed so as to contact the conductive plugs 121. A third interlayer insulation film 122a, which is to form a lower electrode, and a fourth interlayer insulation film 122b are provided by being layered on the second interlayer insulation film 119. The fourth interlayer insulation film 122b is left in the peripheral circuit region, and crown-shaped lower electrodes 123 are formed in the memory cell region. After that, the fourth interlayer insulation film 122b in the memory cell region is removed. A dielectric film 124 is provided so as to cover the inside and outside walls of the lower electrode 123, which is exposed by removing the fourth interlayer insulation film 122b. An upper electrode 125 is provided so as to cover the entire memory cell region. In this way, the capacitor is realized. A support film 122c is provided on a portion of the upper side surface of the lower electrode 123 so as to connect portions of a plurality of adjacent lower electrodes. The support film 122c can improve the mechanical strength, thereby preventing the lower electrode from collapse. Since a space is provided under the support film 122c, the dielectric film 124 and the upper electrode 125 are also provided on the surface of the lower electrode, which is exposed into the space. FIG. 6 shows two capacitors, indicated by Cp1 and Cp2. The lower electrode 123 is made of titanium nitride (TiN), which is formed via chemical vapor deposition (CVD) that has excellent step coverage. The capacitors are covered with a fifth interlayer insulation film 126. The material of the plug may vary depending on the lower electrode of the capacitor, and is not limited to silicon. The plug material may be implemented as a metal that is the same as or different from the material of the lower electrode of the capacitor. In addition, the detailed construction of the dielectric film 124 and the upper electrode 125 will be described in the following manufacturing process.

In the second p-well 104, the transistor, which constitutes the peripheral circuit, includes the source 109, the drain 112, the gate insulation film 110, and the gate electrode 111. A contact-hole, which is provided in a predetermined region of the first interlayer insulation film 113, is filled with metal silicide 116 and tungsten 117 so as to contact the drain 112. A first wiring layer 118 made of tungsten nitride and tungsten is provided so as to contact the tungsten 117. A portion of the first wiring layer 118 is in contact with a second wiring layer 130 made of aluminum or copper via a metal via plug 127, which is provided so as to extend through the second interlayer insulation film 119, the third interlayer insulation film 122a, the fourth interlayer insulation film 122b and fifth interlayer insulation film 126. In addition, a portion of the upper electrode 125 of the capacitor, which is provided in the memory cell region, is led out as a lead line 128 to the peripheral circuit region, and contacts the second wiring layer 130 made of aluminum or copper via a metal plug 129, which is formed in a predetermined region of the fifth interlayer insulation film 126. Afterwards, the formation of an interlayer insulation film, the formation of a contact, and the formation of a wiring layer are repeated as required, thereby constructing DRAM.

FIG. 7 is a schematic plan view of the position marked by X-X in FIG. 6. In FIG. 7, the dielectric film and the upper electrode are omitted. The segment region indicated by Y-Y in FIG. 7 corresponds to the segment region indicated by X-X in FIG. 6. As support film 122c, which covers the entire outside region of the respective lower electrode 123, extends over a plurality of lower electrodes, a plurality of openings 131 is formed in the entire memory cell region. Each lower electrode 123 is configured such that a portion of the outer circumference thereof is in contact with one of the openings 131. Since the support film except for the openings is continuous, the respective lower electrodes are connected to each other via the support film. As a result, it is possible to increase the length in the lateral direction in the aspect ratio, thereby preventing the lower electrodes from collapse. Due to the progressing degree of integration so that the cell is micronized, the aspect ratio of the lower electrode of the capacitor increases. Then, the lower electrode may collapse during the manufacturing process, if a means for supporting the lower electrode is not provided. FIG. 7 shows an example in which the openings 131 are provided so as to extend over 6 lower electrodes around the region, on both sides of which the capacitor Cp1 and the capacitor Cp2 oppose each other. Therefore, the construction corresponding to FIG. 7 is also provided in FIG. 6, in which no support film is provided on the upper portion of the capacitor Cp1, on the upper portion of the capacitor Cp2, and on the upper portion between the capacitors Cp1 and Cp2.

Since the support film is provided in this way, a film-forming method having better coverage is necessary in order to form the dielectric film or the upper electrode on the surface of the lower electrodes, which are below the support film.

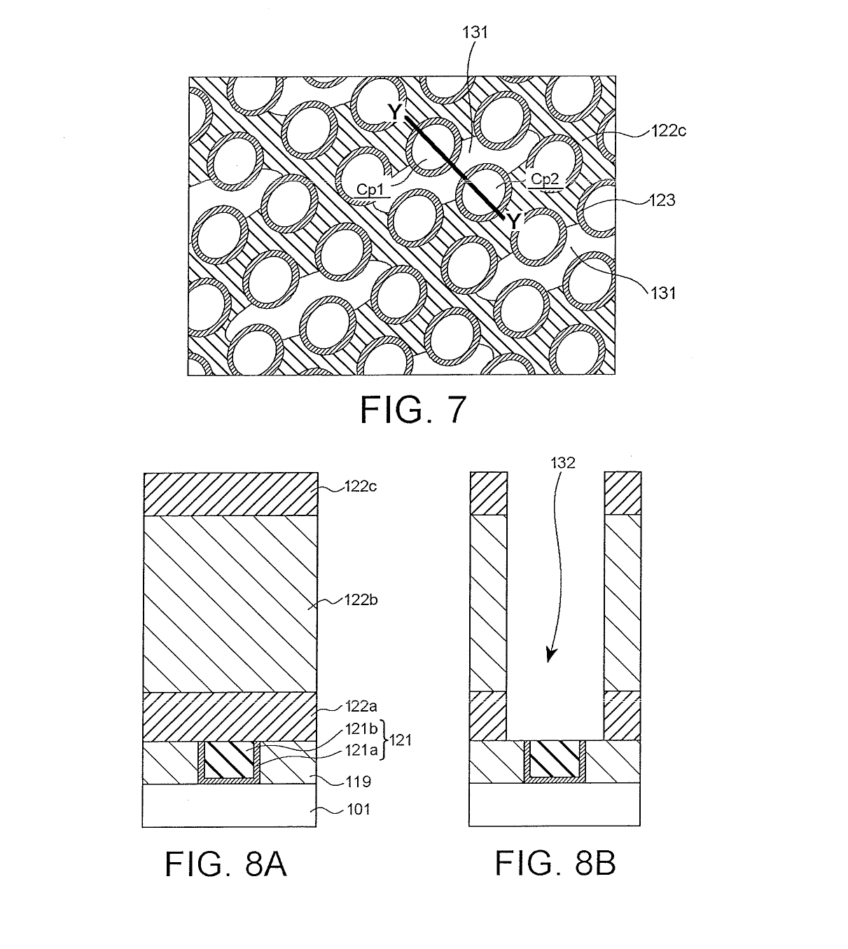

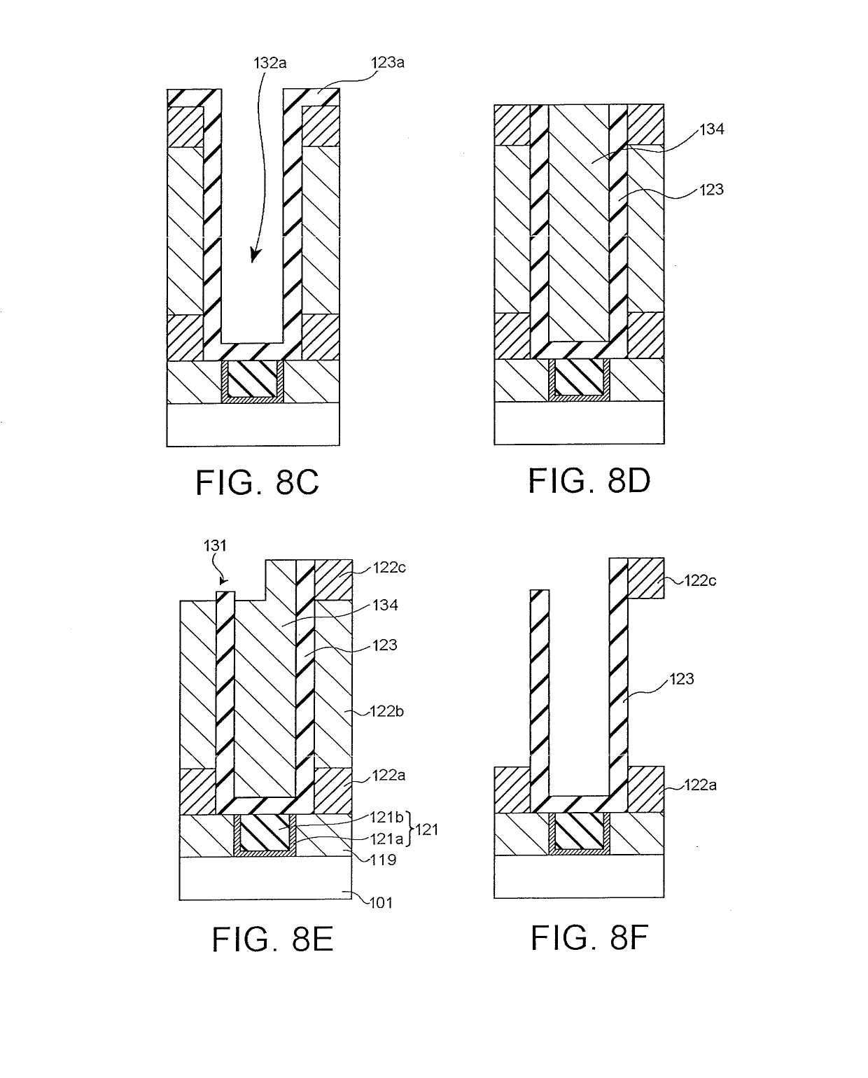

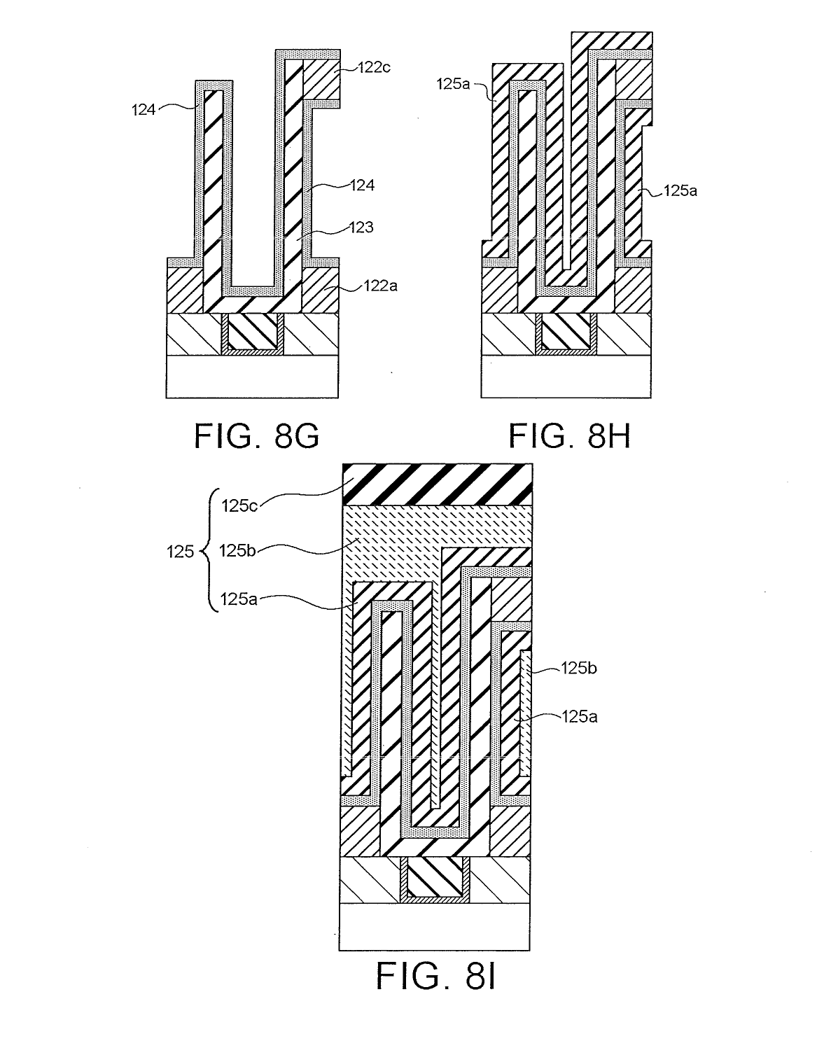

Hereinafter, in the process of manufacturing DRAM, only the process of manufacturing a capacitor according to the invention will be described, but descriptions of the other processes except for the capacitor manufacturing process will be omitted. FIG. 8A to FIG. 8I are cross-sectional views depicting the processes of manufacturing the capacitor shown in FIG. 6. For the sake of explanation, transistors, the first interlayer insulation film and the like on the semiconductor substrate 101 are omitted.

First, as shown in FIG. 8A, the second interlayer insulation film 119 is formed on the semiconductor substrate 101 made of monocrystal silicon.

Afterwards, a contact-hole is opened in a predetermined position and barrier metal 121a and metal 121b are formed on the entire surface of the semiconductor substrate. After that, the portion of the barrier metal 121a and the portion of the metal 121b, which are formed on the second interlayer insulation film 119, are removed using a CMP method, so that a conductive plug 121 is formed. In sequence, the third interlayer insulation film 122a made of silicon nitride, the fourth interlayer insulation film 122b made of silicon oxide, and the support film 122c made of silicon nitride are layered on the entire surface.

After that, as shown in FIG. 8B, a cylinder-hole 132 is formed through the support film 122c, the fourth interlayer insulation film 122b and the third interlayer insulation film 122a using lithography and dry etching technologies. The cylinder-hole is formed such that it is a circle having a diameter of 60 nm when viewed on the plane. In addition, the cylinder-hole is formed such that the closest interval from an adjacent cylinder-hole is 60 nm. In this way, the upper surface of the conductive plug 121 is exposed on the bottom of the cylinder-hole.

In sequence, as shown in FIG. 8C, a TiN film 123a, which is to be a material for the lower electrode of the capacitor, is formed on the entire surface including the inner surface of the cylinder-hole 132. The TiN film may be formed at a temperature ranging from 380° C. to 650° C. through a CVD method using TiCl₄ and NH₃ as sources. In this embodiment, the TiN film is formed at 450° C. The film thickness is set to be 10 nm. The TiN film may be formed through an ALD method using the foregoing sources. Due to the formation of the TiN film 123a, a new cylinder-hole 132a is formed. The thickness of the TiN film may be determined such that the actual film thickness at the side wall of the hole is in the range from 5 nm to 15 nm.

As shown in FIG. 8D, a protective film 134, such as a silicon oxide film, is formed on the entire surface in order to bury the cylinder-hole 132a. After that, the portion of the protective film 132 and the portion of the TiN film 123a, which are formed on the upper surface of the support film 122c, are removed, thereby forming a lower electrode 123.

In sequence, as shown in FIG. 8E, openings 131 are formed in the support film 122c. As shown in the plan view of FIG. 7, the pattern of the opening 131 overlaps with a part of the fourth interlayer insulation film 122b, a part of the lower electrode 123, and a part of the protective film 134 remaining in the inside of the lower electrode. Therefore, dry-etching for forming opening 231 removes a portion of the top of lower electrode 123 and the protective film 134 as well as the support film 122c formed on fourth interlayer insulation film 122b.

Afterwards, as shown in FIG. 8F, the fourth interlayer insulation film 122b, which is exposed inside the opening 131, is removed. For example, when the fourth interlayer insulation film is etched using hydrofluoric acid solution (HF solution), the support film 122c is rarely etched since it is made of silicon nitride, but both the fourth interlayer insulation film 122b and the protective film 134, which are made of silicon oxide, are removed. Due to the etching is performed using the etching solution, the silicon oxide film that is not only directly under the opening 131 but also under the support film 122c is removed. Due to this, the support film 122c, which supports the lower electrode 123 and the lower electrode 123, remains in a hollow space, and the surface of the lower electrode 123 is exposed.

In this etching, the third interlayer insulation film 122c made of silicon nitride functions as an etching stopper, thereby preventing the second interlayer insulation film 119 from being etched.

In sequence, as shown in FIG. 8G, a dielectric film 124 is formed. The dielectric film 124 has a total thickness of 8 nm, which includes, from the lower electrode, 1 nm to 4 nm of a ZrO film portion and 4 nm to 7 nm of an Al-doped TiO film portion. Since the film formed through the ALD method has excellent step coverage, the dielectric film 124 is formed on the entire portion of the lower electrode surface, which is exposed in the hollow space. The dielectric film 124 is not limited to this example, but may be implemented as an Al-doped ZrO film formed on the lower electrode or a multilayer structure of an Al-doped ZrO film and an Al-doped TiO film as explained above.

Afterwards, as shown in FIG. 8H, a RuO₂ film, which is to form a first upper electrode 125a, is formed. The thickness of this film is set to be 10 nm.

In sequence, as shown in FIG. 8I, a boron (B)-doped silicon-germanium film (B—SiGe film), which is to form a second upper electrode 125b, is formed. In the step of forming the first upper electrode 125a in FIG. 8H, the hollow space still remains, and spaces reside in several places. In this state, if tungsten, which is to form a plate electrode 125c, is formed via a physical vapor deposition (PVD) method, the spaces are not completely filled up because the PVD method has bad step coverage. Even in the step in which the semiconductor device is completed, spaces reside around the capacitor. The residual spaces lead to a decrease in mechanical strength, thereby causing a problem in that characteristics of the capacitor vary due to stress that occurs in the following package process. Therefore, the purpose of forming the B—SiGe film is to improve resistance to mechanical stress by filling up and removing the residual spaces.

The B—SiGe film can be formed through a CVD method using germane (GeH₄), monosilane (SiH₄) and boron trichloride (BCl₃) as sources. The B—SiGe film, which is formed through this CVD method, has excellent step coverage, and can fill up the hollow spaces.

After the B—SiGe film, which is to form the second upper electrode 125b, a tungsten (W) film is formed, which is to form the third upper electrode 125c, in order to use the resultant structure as a current supply plate that covers the entire memory cell region. The W film can be formed through a PVD method at a temperature ranging from 25° C. to 300° C. The structure covering from the first upper electrode 125a to the third upper electrode 125c is referred to as the upper electrode 125, as shown in FIG. 6. After that, as shown in FIG. 6, the process of forming the fifth interlayer insulation film 126 and the following process are performed, thereby producing a semiconductor device of DRAM.

The DRAM described in this exemplary embodiment relates to the construction of most advanced DRAM having an ultra-high density and the method of manufacturing the same. Even with the three-dimensional structure, if it is not necessary to reinforce the structure, the process of forming B—SiGe is not necessary.

In the case of the TiO film having a rutile crystalline structure, the permittivity can be increased up to the range approximately from 60 to 80, and thus EOT can be made smaller than that of the TiO film having an anatase crystalline structure. As a result, application to DRAM for F=30 nm-node and below is made possible.

What is claimed is:

1. A method of forming a titanium oxide film having a rutile crystalline structure, comprising:
forming an amorphous zirconium oxide film;
forming an amorphous titanium oxide film on the amorphous zirconium oxide film using methyl cyclopentadienyl tris(dimethylamino) titanium as a titanium precursor by an atomic layer deposition (ALD) method; and
crystallizing at least the amorphous titanium oxide film by annealing at a temperature of 300° C. or higher.

2. The method of forming a titanium oxide film according to claim 1, wherein the forming an amorphous zirconium oxide film comprises forming a zirconium oxide film by an ALD method at a film thickness ranging from 0.1 nm to 4 nm.

3. The method of forming a titanium oxide film according to claim 1, wherein the forming an amorphous titanium oxide film by an ALD method is performed at a temperature below 300° C.

4. The method of forming a titanium oxide film according to claim 1, wherein the forming an amorphous titanium oxide film by an ALD method comprises repeatedly performing a cycle until a thickness of the amorphous titanium oxide film becomes 3.5 nm or more, the cycle comprising processes of (1) introducing the titanium precursor into a reaction chamber and causing the titanium precursor to be adsorbed on a surface of the amorphous zirconium oxide film, (2) discharging a portion of the titanium precursor that is not adsorbed by a purge gas from the reaction chamber, (3) oxidizing the titanium precursor using a reaction gas, and (4) purging a portion of the reaction gas that has not reacted.

5. A method of manufacturing a semiconductor device, which includes a capacitor, the method comprising:
forming an amorphous zirconium oxide film on a lower electrode for the capacitor;
forming an amorphous titanium oxide film on the zirconium oxide film using methyl cyclopentadienyl tris(dimethylamino)titanium as a titanium precursor by an atomic layer deposition (ALD) method;
crystallizing at least the amorphous titanium oxide film by annealing at a temperature ranging from 300° C. to 700° C.; and
forming an upper electrode for the capacitor on the annealed titanium oxide film.

6. The method of manufacturing a semiconductor device according to claim 5, wherein the forming an amorphous zirconium oxide film comprises forming a zirconium oxide film by an ALD method at a film thickness ranging from 0.1 nm to 4 nm.

7. The method of manufacturing a semiconductor device according to claim 5, wherein the forming an amorphous titanium oxide film by an ALD method is performed at a temperature below 300° C.

8. The method of manufacturing a semiconductor device according to claim 5, wherein the forming an amorphous titanium oxide film using by an ALD method comprises repeatedly performing a cycle until a thickness of the amorphous titanium oxide film becomes 3.5 nm or more, the cycle comprising processes of (1) introducing the titanium precursor into a reaction chamber and causing the titanium precursor to be adsorbed on a surface of the amorphous zirconium oxide film, (2) discharging a portion of the titanium precursor that is not adsorbed by a purge gas from the reaction chamber, (3) oxidizing the titanium precursor using a reaction gas, and (4) purging a portion of the reaction gas that has not reacted.

9. The method of manufacturing a semiconductor device according to claim 5, wherein the crystallizing by annealing is performed in an oxidizing atmosphere.

10. The method of manufacturing a semiconductor device according to claim 5, wherein at least one of the forming an amorphous zirconium oxide and the forming an amorphous titanium oxide film comprises forming an aluminum-doped layer.

11. The method of manufacturing a semiconductor device according to claim 10, wherein, in the aluminum-doped layer, a plane density of Al atoms in one layer is less than 1.4 E+14 atoms/cm².

12. The method of manufacturing a semiconductor device according to claim 5, wherein a TiN film or a film having a work function of 5.1 eV or higher is formed as the lower electrode.

13. The method of manufacturing a semiconductor device according to claim 5, wherein the forming an upper electrode comprises forming a film having a work function of 5.1 eV or higher on a portion that is in contact with the titanium oxide film.

14. The method of manufacturing a semiconductor device according to claim 13, wherein the lower electrode is formed in a crown shape and the method further comprising forming a support film in contact with the upper portion of the lower electrode.

15. The method of manufacturing a semiconductor device according to claim 14, wherein the forming an upper electrode further comprises, following the forming a film having a work function of 5.1 eV or higher, forming a second upper electrode made of a boron-doped silicon-germanium film.
